(19) United States
(12) Patent Application Publication
(10) Pub. No.: US 2006/0197096 A1
(43) Pub. Date: Sep. 7, 2006

(54) Substrate with refractive index matching

(76) Inventors: Sebastien Kerdiles, Saint Ismier (FR); Yves-Mathieu Le Vaillant, Crolles (FR)

Correspondence Address: WINSTON & STRAWN LLP, 1700 K STREET, N.W., WASHINGTON, DC, 20006, US

(21) Appl. No.: 11/412,215

(22) Filed: Apr. 25, 2006

Related U.S. Application Data
(63) Continuation of application No. PCT/EP04/12255, filed on Oct. 29, 2004.

(30) Foreign Application Priority Data
Oct. 30, 2003 (FR) 0312719

(51) Int. Cl. H01L 21/00; B32B 17/06; H01L 29/26; H01L 27/15

(52) U.S. Cl. 257/79; 428/698; 428/701; 428/702; 428/432; 428/446; 438/22

(57) ABSTRACT

This invention provides a composite substrate that has a transparent mechanical support, for example of glass or quartz, a film or thin layer of monocrystalline semi-conductive material and an intermediate antireflective layer located between the thin layer or the semi-conductive film and the support. The composition of the intermediate antireflective layer varies between the support and the semi-conductive film, so that the refractive index similarly varies.

### CROSS-REFERENCE TO RELATED APPLICATIONS

This application is a continuation of International application PCT/EP2004/012255 filed Oct. 29, 2004, the entire content of which is expressly incorporated herein by reference thereto.

### FIELD OF THE INVENTION

The invention relates to the fields of optics and optoelectronics, microelectronics, and semiconductors. In particular, the invention provides light-emitting components (light-emitting diodes (LEDs), laser diodes (LDs), etc), or light-receiving and/or detecting components-(solar cells, photodiodes, etc).

The invention also provides devices or components that pass light, for example those in which the intensity or polarization is intentionally modified by that device or component. Examples of such devices are active filters, active matrices for organic LEDs, and active matrices for liquid crystal displays (LCDs).

### BACKGROUND OF THE INVENTION

In a large proportion of the components cited above, the active layers, constituted by semi-conductive materials (Si, SiC, Ge, SiGe, GaN, AlGaN, InGaN, GaAs, InP, etc), designed to emit, receive, or modify light, are produced on a transparent substrate such as glass, sapphire, or quartz to maximize the light yield of the component.

As an example, active matrices used to produce flat screens based on OLEDs organic LEDs) are produced from a glass substrate on which a thin film of silicon has been formed, which film is usually polycrystalline and, more rarely, monocrystalline. The light emitted by the LEDs then passes through the mechanical support of glass or, possibly, quartz.

In another example, to allow light to be extracted, again through the substrate, LEDs emitting in the green or blue are generally fabricated from thin layers of GaN, grown epitaxially on a sapphire substrate.

Designers of such components strive to minimize light losses, and as such generally produce specific geometries (surface texturing, LEDs in the form of pyramids, etc) and/or antireflective coatings encapsulating the component.

Transparent substrates such as glass, quartz, and to a lesser extent sapphire, have refractive indices n which are substantially lower (n<1.8) than the semi-conductive materials constituting the active layers (n˜3) (see Table 1 for a wavelength of 500 nanometers (nm)). This difference in index n is the source of light losses by reflection at the interface between the transparent and the semi-conductive layers. At the interface between two media with indices n1 and n2, the reflection coefficient (at normal incidence) is given by:
R=(n1−n2)2/(n1+n2)ˆ2

Reflective losses at the interface between two materials with different indices are thus proportional to the square of the difference in the indices.

TABLE 1
Refractive index (λ˜500 nm) of the principal transparent substrates
and of a few semi-conductive materials.

| | Refractive | | Refractive |
|---|---|---|---|
| Transparent substrates | index (n) | Semiconductors | index (n) |
| Corning 1737 glass | 1.52 | Si | 3.4 |
| Quartz | 1.48 | Ge | 4.0 |
| Sapphire | 1.77 | GaAs | 3.7 |
| | | InP | 3.5 |
| | | GaN | 2.3 |
| | | SiC | 2.7 |

As an example, Si/quartz and GaAs/glass interfaces result respectively in about 16% and 19% losses of light by reflection.

These light losses, due solely to the interface between the substrate and the active semi-conductive layer, must be added to the losses that occur at the substrate/air interface (bottom face of the structure, for example, air/glass: 4%) and at the interface between air and the active semi-conductive layer (top face of the structure, for example, air/Si: 30%).

The two interfaces with air on either side of the structure may undergo an antireflective treatment at the end of the component fabrication process. In contrast, the internal transparent substrate/semiconductor interface can be improved only prior to fabrication of the component, i.e., during preparation of the composite substrate, before applying the thin film of semiconductor to the transparent support.

Developments in applications employing a transparent substrate such as glass or quartz surmounted by a thin film of silicon were initially based on hydrogenated amorphous silicon obtained by chemical vapor deposition (CVD), later on polycrystalline silicon obtained by recrystallizing amorphous silicon.

Recently, a new generation of components based on monocrystalline silicon have been developed, which components benefit from better electron and hole mobility. To meet the requirements for these emerging lines, new substrates have appeared, such as SOG (silicon on glass) or SOQ (silicon on quartz) type structures comprising a than film of monocrystalline silicon directly applied to the transparent support. An intermediate layer of SiO₂ can optionally be interposed between the two, thus producing a glass/SiO₂/Si structure. Unfortunately, that does not reduce reflective losses.

Thus, the problem arises of discovering novel structures, and corresponding fabrication methods, capable of reducing the losses that are currently encountered.

### SUMMARY OF THE INVENTION

The invention provides a composite substrate comprising a transparent mechanical support, for example of glass or quartz, a film or thin layer of monocrystalline semi-conductive material and an intermediate layer, located between the thin layer or the semi-conductive film and the support, having optical characteristics (thickness, refractive index and absorption) that are selected to avoid or limit reflective light losses within the composite substrate on the optical path between the support and the semi-conductive film.

The invention also provides a composite substrate comprising a transparent support, a thin layer or film of semi-conductive material and a buried thin antireflective film between the transparent support and the thin film or the semi-conductive film.

The semi-conductive material constituting the semi-conductive film is, for example, selected from Si, Ge, SiGe, SiC, GaAs, GaP, InP, AlGaInP, GaN, AlN, AlGaN, InGaN, and AlGaInN.

The thin antireflective film may comprise an oxide, nitride or carbide, e.g., silicon oxide, silicon nitride, silicon carbide, gallium nitride or aluminum nitride. The thin antireflective film may also comprise a mixture of these types of materials, e.g., silicon oxynitride SiOₓN_{y} or SiCₓN_{y}. Said mixtures can be deposited in the form of than films by PECVD (plasma enhanced chemical vapor deposition) and can optionally be hydrogenated.

In accordance with the invention, the composition of the thin antireflective layer varies (gradually or continuously) between the surface and the semi-conductive film. As the composition varies, the refractive index of the thin antireflective layer also varies.

In a first embodiment, the thin antireflective layer, which is buried in the composite substrate, comprises a stack of sublayers based on the above-mentioned materials. The composition of the antireflective layer then varies gradually from one sub-layer to another. Preferably, each sub-layer has a refractive index ni close to (ni+1×ni−1)ˆ(½), in which ni+1, ni−1 are the indices of materials either side of the sub-layer in question.

In a second embodiment, the thin antireflective layer comprises one or more sub-layers having compositions that vary continuously between the substrate and the semi-conductive film so that the refractive index similarly varies.

As an example, the thin antireflective film can be constituted by SiO2 in contact with the substrate, then the oxynitride SiOₓN_{y} with a proportion of nitrogen that is continuously augmented until SiO₃N₄ is formed close to the semi-conductive layer.

The preceding thin layer can also be combined with a film of SiCₓN_{y} having a carbon concentration that is progressively augmented (x increasing towards 1) to the detriment of that of nitrogen (y decreasing towards 0) on approaching the semi-conductive layer. Said varying combination allows the formation of a buried antireflective layer the refractive index of which varies continuously from about 1.5 to about 2.6 because of a progressive transition between SiO₂ and SiC via Si₃N₄.

The thin antireflective layer(s) can be electrical insulators.

The invention also provides a light emitting or receiving device comprising a composite substrate as described above, and having light emitting or detecting means at least partially formed in and/or on the semi-conductive material layer. In particular, such a light emitting device can be based on light emitting diodes. Such a light sensor or detecting device can serve as a photodetector, or a solar cell, or an active matrix for image projection.

The invention also provides a method of producing a composite substrate, said substrate comprising a transparent support, a thin film of semi-conductive material and at least one thin antireflective layer buried between the transparent support and the semi-conductive film, said method comprising the following steps:

producing at least one thin antireflective layer on the transparent support or on a substrate of semi-conductive material, said thin antireflective layer having a composition that varies to vary the refractive index between the support and the semi-conductive film;

assembling the transparent support and the substrate of semi-conductive material so that the thin layer is located between the two;

thinning the substrate of semi-conductive material.

The transparent support and semi-conductive material substrate can be assembled together by molecular bonding, for example. The step for thinning the semi-conductive substrate can be carried out by forming a layer or zone of weakness. The thinning step can also be carried out by polishing or etching. The layer or zone of weakness can be, for example, produced by forming a layer of porous silicon or by implanting ions such as hydrogen ions, or a mixture of hydrogen ions and helium ions, in the semi-conductive substrate.

Further aspects and details and alternate combinations of the elements of this invention will be apparent from the following detailed description and are also within the scope of the inventor's invention.

### BRIEF DESCRIPTION OF THE DRAWINGS

The present invention may be understood more fully by reference to the following detailed description of the preferred embodiment of the present invention, illustrative examples of specific embodiments of the invention and the appended figures in which:

FIGS. 1 and 2 show a structure in accordance with the invention;

FIGS. 3A to 3F show steps in a production method in accordance with the invention;

FIGS. 4A to 4D show steps in another production method of the invention.

### DETAIL DESCRIPTION OF THE PREFERRED EMBODIMENTS

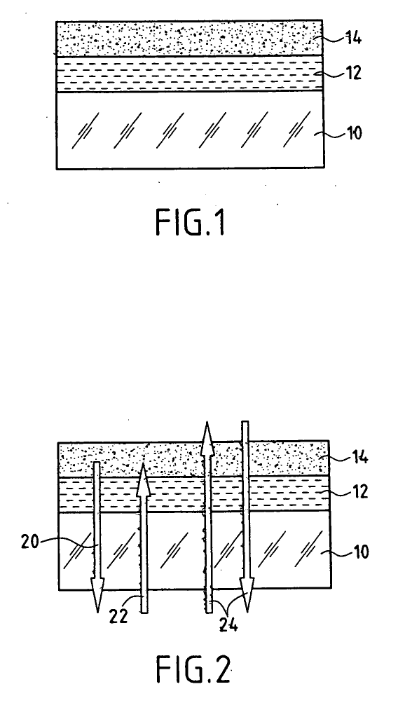

FIG. 1 shows an example of a structure in accordance with the invention. Firstly, it includes a transparent support 10, preferably comprising glass, quartz (fused silica), or sapphire. Any other material that is transparent to radiation and that can be used in the component fabricated from said substrate, could also act as a support. As an example, when infrared radiation sensors are produced, a silicon support can advantageously be used.

A thin film 14 formed of semi-conductive material, preferably monocrystalline material, is separated from the support by one or more thin antireflective layers 12. The semi-conductive material comprising the film 14 is preferably selected from Si, Ge, SiGe, SiC, GaAs, GaP, InP, AlGaInP, GaN, AlN, AlGaN, InGaN, and AlGaInN.

The intermediate antireflective layer, or the set of intermediate antireflective layers 12, preferably comprises materials that are compatible with methods for producing components from a thin film of semiconductor which surmounts the buried antireflective layer. Most preferably, materials that are unstable at low temperatures or that contain metals that may diffuse through the film 14 and/or damage or perturb the function of the component are avoided.

The intermediate antireflective layer 12 comprises at least one layer of insulating material(s) in order to avoid producing any paths for electrical conduction between the semi-conductive film 14 and the transparent support 10. Thereby, devices of this invention have advantageous properties similar to SO1 type structures (semiconductor on insulator), in particular from the low power consumption of the components and their better high frequency (RF) performance.

This intermediate layer 12 preferably comprises an oxide, nitride, or a mixture of oxide and nitride. In particular, it can includes silicon oxide, silicon nitride, silicon carbide or gallium nitride, or alloys such as silicon oxynitride SiOxNy or SiCxNy.

The intermediate layer can include a stack of a plurality of layers formed from the same material or different materials, the optical properties of which (thickness, absorption, coefficient and refractive index) are selected to reduce the quantity of light lost by internal reflections between the transparent support 10 and the semi-conductive film 14. The intermediate layer 12 can also comprises a layer of composition that varies continuously to cause the refractive index to vary progressively between the substrate 10 and the film 14. In particular, the layer 12 can comprises SiO₂ (substantially pure or with a small SiOₓN_{y} component) in contact with the transparent glass or quartz support then by oxynitride SiOxNy with a proportion of nitrogen that progressively increases until Si₃N₄ (substantially pure or with a small SiOₓN_{y} component) is formed in the last nanometers of said intermediate layer close to the semi-conductive film.

In contrast, the thin antireflective layer can be constituted by SiO₂ in contact with the support 10, then SiOₓN_{y} with a proportion of nitrogen which reduces and a proportion of carbon which increases until SiC is formed close to the semi-conductive layer. In another variation, the layer 12 can be constituted by Si₃N₄ in contact with the transparent support, then by SiOₓN_{y} with a proportion of nitrogen which reduces and a proportion of carbon which increases until SiC is formed close to the semi-conductive layer.

The thickness of the intermediate antireflective layer 12, or of each sub-layer of a stack of sub-layers, is approximately in the range 0.05 micrometers (μm) to 1 μm. It is preferably equal to about a quarter of the mean wavelength emitted, captured, or transmitted by the component produced on the composite substrate (or an odd number of quarter-wavelengths). As an example, if the component in question is a solar cell based on silicon transferred onto quartz, the thickness of the intermediate layer 12 is set at approximately 0.13 μm so that it is optimized for solar radiation centered on 0.55 μm.

The refractive index of the material constituting the layer or sub-layer is preferably close to the value corresponding to ni−(ni+1×ni−1)ˆ(½), in which ni+1, ni−1 are the refractive indices of materials on either side of the layer in question.

As an example, an intermediate layer inserted between a glass support (n˜1.5) and a film of GaAs (n˜3.7) preferably comprises a transparent material with an index close to (1.5×3.7)ˆ(½)=2.6. A film of silicon nitride may then be suitable, as would be a film of GaN.

In another example, for a stack of two layers inserted between a quartz support and a silicon film (n˜3.4), the index of two successive layers is preferably selected to be about 1.95 (=(1.5×2.6)ˆ(½)) and 2.6 (=(1.95×3.4)ˆ(½)). A film of silicon oxynitride and a film hydrogenated amorphous silicon (a-Si:H) or hydrogenated amorphous silicon carbide (a-SiC:H) may also be suitable.

The optical properties of the buried layer, such as thickness and/or the absorption coefficient and/or the refractive index of the material constituting it, are thus preferably selected or optimized to limit reflective losses in the composite substrate.

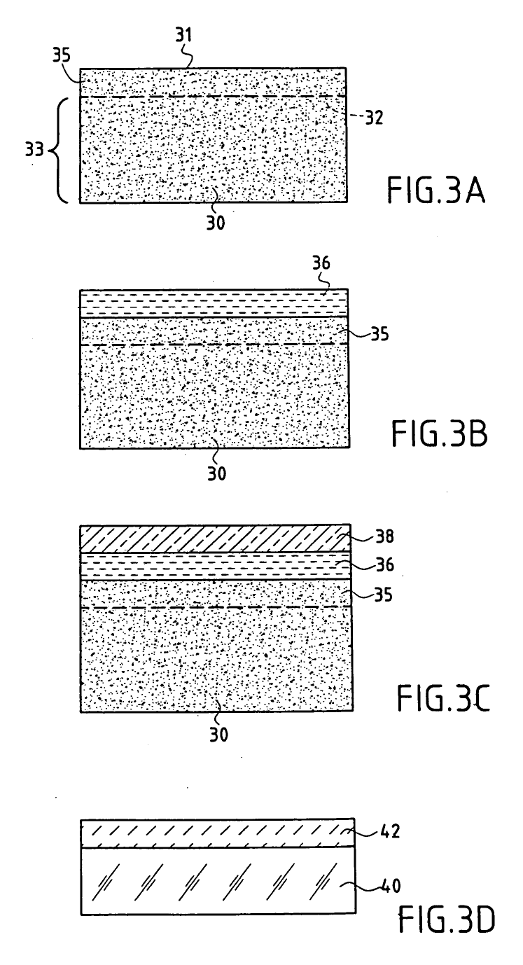

As shown in FIG. 2, the intermediate layer 12, comprising one or more stacked layers, matches the “optical impedance” between the transparent support 10 and the semi-conductive film 14 so that:

light 20 emitted from the layer 14 or other layers deposited thereon passes through the composite substrate thereby suffering limited reflective losses; there is thus an improvement in the extraction of light produced by the means or a light-emitting device such as one or more light-emitting diode(s) produced from or in the layer 14;

light 22 reaching the layer 14 or other layers deposited thereon passes through the composite substrate with better efficiency; thus, there is an improvement in the function of an element or light capture or detector means such as one or more photo-detector(s) or such as one or more solar cell (s) produced in the layer 14;

light 24 passes through the composite substrate from one side to the other with little loss; thus, components or means which are produced in the layer 14, such as active matrices for image projection, are improved.

The techniques for forming a device in accordance with the invention preferably comprise a step of assembling together two substrates or supports, one of which is transparent and the other of which is semi-conductive, and a step of thinning the semi-conductive material substrate. The intermediate antireflective layer can be formed prior to the step of assembling on the transparent support and/or on the surface of the semi-conductive material.

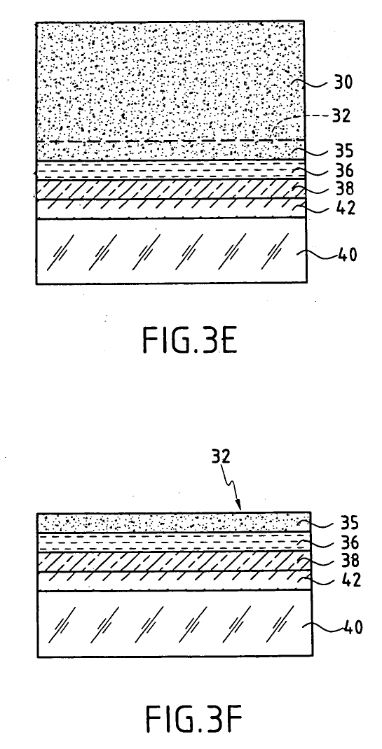

In a particular implementation, shown in FIG. 3A, atomic or ionic implantation is carried out in a semi-conductive substrate 30 (see FIG. 3A, for example), forming a thin layer 32 which extends substantially parallel to a surface 31 of the substrate 30. In fact, a layer or zone of weakness or fracture zone is formed which defines a region 35 in the bulk of the substrate intended to constitute a thin film and a region 33 constituting the mass of the substrate 30. This implantation is generally hydrogen implantation, but can also be carried out using other species, or with H/He co-implantation.

Substrate 30, on which one (FIG. 3B) or some (FIG. 3C) antireflective layer(s) 35, 38 is/are formed, is then assembled with a transparent substrate 40, on which an antireflective layer 42 can also optionally be formed (FIG. 3D). Such an assembly step is shown in FIG. 3E, and is performed, for example, using a “wafer bonding” type technique, for example molecular or other bonding. For information regarding those techniques, reference should be made to the work by Q. Y. Tong and U. Gosele, “Semiconductor Wafer Bonding” (Science and Technology), Wiley Interscience Publications.

A portion of the substrate 30 is then detached by a treatment that can cause fracture along the plane of weakness 32. An example of this technique is described in the article by B. Aspar et al, “The generic nature of the Smart-Cut(r) process for thin film transfer” in the Journal of Electronic Materials, vol. 30, No. 7 (2001), p 834-840.

That technique is also described in U.S. Pat. No. 5,374,564. The thin film is then bonded to the transparent support via a bonding interface obtained by molecular bonding, while cleavage is the result of implanting ions, followed by heat treatment.

A plane of weakness can be formed using methods other than ion implantation. Thus, it is also possible to produce a layer of porous silicon, as described in the article by T. Yonehara et al, “Epitaxial layer transfer by bond and etch back of porous Si”, in Applied Physic s Letters, vol. 64, no. 16 (1994), p 2108-2110, or in European patent document EP-A-0 925 888.

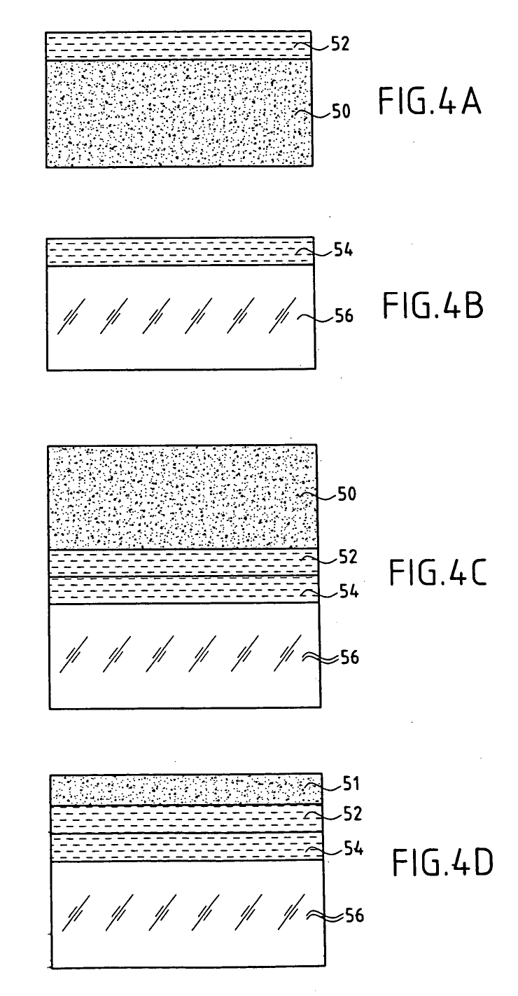

In a further particular implementation, one or more antireflective layers 52 are produced on a semi-conductive substrate 50 (FIG. 4A) and optionally one or more antireflective layers 54 are produced on a transparent substrate 56 (FIG. 4B). Said two substrates are then assembled together using the techniques described above (FIG. 4C). The substrate 50 is then thinned using polishing or etching techniques (FIG. 4D).

### EXAMPLES

Three examples are given below.

### Example 1

This example concerns a composite substrate comprising a thin silicon film, a transparent quartz support, and a buried antireflective layer constituted by two sub-layers. The composite substrate so produced is suitable for a component that can detect light with a wavelength centered around 500 nm.

1. Firstly (FIG. 3A), ionic implantation of hydrogen is carried out in a silicon substrate 30.

2. A first layer 36 of the desired thickness (for example 125 nm) and constituted by amorphous silicon carbide (n˜2.6) is then applied (FIG. 3B) to the surface of implanted Si, by cathode sputtering or by chemical vapor decomposition (CVD).

3. A second layer 38 constituted by SiOₓN_{y} (n−1.95) is applied using CVD (FIG. 3C). Polishing this deposit produces the desired thickness, for example 125 nm, and a surface that is sufficiently smooth to carry out bonding by molecular bonding.

4. A deposit 42 of silicon oxide is then produced on the quartz support 40 (FIG. 3D). Polishing said deposit can smooth the surface for bonding by molecular bonding.

5. The surfaces are cleaned. Then, substrate Si surmounted by the two said deposits 36, 38 is bonded by molecular bonding to the transparent quartz support 40 surmounted by the deposit of oxide 42 (FIG. 3F).

6. Heat treatment fractures the substrate 30 (the treatment is also known as the SMART-CUT® process) (FIG. 3F). This cleaves the silicon substrate 30 at the implanted zone 32 and forms a layer of semi-conductive material 35.

7. Optionally, the surface of the composite substrate can be finished, for example by chemical/mechanical polishing or by using a smoothing hydrogen anneal.

The technique used to transfer the thin semi-conductive film is in this case the substrate fracture technique or SMART-CUT® process (implantation+bonding+thermal or possibly mechanical fracture).

### Example 2

This example concerns the production of a composite substrate comprising a thin film of GaAs, a transparent glass support and a simple antireflective layer. The composite substrate so produced is suitable for an LED emitting at 640 nm:

1. Firstly, a deposit 52 (which is optionally smoothed) of 160 nm of amorphous or polycrystalline gallium nitride (n˜2.3) is made on a monocrystalline GaAs substrate 50 which has been cleaned in advance 10 (FIG. 4A).

2. Then a deposit 54 of SiO2, which is optionally planarized, is produced on the glass support 56 which has been cleaned in advance (FIG. 4B)

3. After cleaning, the transparent support 56 is bonded by molecular bonding to the GaAs substrate 50 (GaN face) (FIG. 4C).

4. Mechanical and/or chemical thinning of the GaAs substrate produces a thin film 51 of GaAs of controlled thickness (FIG. 4D).

5. Finally, finishing is carried out on the surface of the composite substrate.

The technique for transferring the thin semi-conductive film is the “bond and etch-back” method, namely bonding followed by thinning from the back face.

### Example 3

This example concerns the production of a composite substrate comprising a thin film of Si, a glass support and a simple antireflective layer. The composite substrate so produced is suitable for a solar cell. It is described in association with the same FIGS. 4A-4D:

1. Firstly, a thin film 52 of transparent conductive oxide is applied to a substrate 50 of Si (FIG. 4A).

2. The desired thickness is obtained by planarization of this layer (for example: 125 nm) and the surface is compatible with bonding by molecular bonding.

3. A layer 54 of SiO₂ is applied to the support 56 of glass, for bonding, and is optionally planarized.

4. Bonding by molecular bonding is then carried out (FIG. 4C) with the transparent conductive oxide face 52 on the SiO₂ face 54. Said bonding is preferably carried out at low temperature to limit diffusion of metallic elements from the conductive oxide to the silicon.

5. Finally, mechanical and/or chemical thinning of the silicon substrate is carried out (FIG. 4D).

6. Optionally, a step for finishing the surface of the composite substrate is carried out.

The preferred embodiments of the invention described above are illustrations of several preferred aspects of the invention and do not limit the scope of the invention. Any equivalent embodiments are intended to be within the scope of this invention.

A number of references are cited herein, the entire disclosures of which are incorporated herein, in their entirety, by reference for all purposes. Further, none of these references, regardless of how characterized above, is admitted as prior to the invention of the subject matter claimed herein.

What is claimed is:

1. A composite semiconductor substrate comprising:
a transparent support;
a film of semi-conductive material; and
at least one antireflective layer between the transparent support and the semi-conductive film, the antireflective layer having a varying index of refraction that depends at least in part on a varying composition of the antireflective layer.

2. The substrate according to claim 1, in which the semi-conductive material comprises Si, Ge, SiGe, SiC, GaAs, GaP, InP, AlGaInP, GaN, AlN, AlGaN, InGaN, and AlGaInN.

3. The substrate according to claim 1, in which the antireflective layer comprises an oxide, nitride, carbide, or a mixture of oxide and nitride.

4. The substrate according to claim 3, in which the antireflective layer comprises silicon oxide, silicon nitride, silicon carbide, silicon oxynitride (SiOₓN_{y}), SiCₓN_{y}, gallium nitride, or aluminum nitride.

5. The substrate according to claim 1, in which the antireflective layer comprises a plurality of stacked sub-layers, with each sub-layer having a refractive index, ni, close to a value determined by the relation (ni+1×ni−1)ˆ(½), in which ni+1, ni−1 are the refractive indices of materials on either side of the sub-layer in question.

6. The substrate according to claim 1, in which the antireflective layer comprises SiO₂ in contact with the support, then silicon oxynitride SiOₓN_{y} with a proportion of nitrogen that is increased until Si₃N₄ is formed close to the semi-conductive layer.

7. The substrate according to claim 1, in which the antireflective layer comprises Si₃N₄ in contact with the support, then SiCₓN_{y} with a proportion of nitrogen that is reduced and a proportion of carbon that is increased until SiC is formed close to the semi-conductive layer.

8. The substrate according to claim 1, in which the antireflective layer comprises SiO2 in contact with the support, then SiOxNy with a proportion of nitrogen that is reduced and a proportion of carbon that is increased until SiC is formed close to the semi-conductive layer.

9. The substrate according to claim 1, in which the antireflective layer is an electrical insulator.

10. The substrate according to claim 1, in which the transparent support comprises glass or quartz and the semi-conductive material comprises gallium arsenide (GaAs).

11. The substrate according to claim 1, in which the transparent support comprises glass or quartz and the semi-conductive material comprises silicon (Si).

12. A light emitting or receiving device comprising:
a composite semiconductor substrate according to claim 1; and
light emitting or detecting means at least partially formed in or on the film of semi-conductive material.

13. A method of producing a composite semiconductor substrate comprising:
producing at least an antireflective layer with a varying index of refraction on a transparent support, the varying index of refraction depending at least in part on a varying composition of the antireflective layer;
assembling the transparent support and a substrate of semi-conductive material so that the antireflective layer is between the transparent support and the semi-conductive substrate; and
thinning the substrate of semi-conductive material to form the composite semiconductor substrate.

14. The method according to claim 13, in which the assembling the transparent support and the semi-conductive substrate comprises molecular bonding.

15. The method according to claim 13, in which the thinning of the semi-conductive substrate comprises producing a layer or zone of weakness and splitting the substrate at or in the zone of weakness.

16. The method according to claim 15, in which the layer or zone of weakness comprises a layer of porous silicon.

17. The method according to claim 15, in which producing the layer or zone of weakness comprises ion implantation in the second semiconductor substrate.

18. The method according to claim 17, in which the implanted ions are hydrogen ions, or a co-implantation of hydrogen ions and helium ions.

19. The method according to claim 13, in which thinning of the semi-conductive substrate comprises polishing or etching.

20. The method according to claim 13, in which the transparent support comprises glass or quartz or a semi-conductive material.

21. The method according to claim 13, wherein the thin antireflective layer is produced to comprise Si₃N₄ in contact with the support, then SiCₓN_{y} with a proportion of nitrogen that is reduced and a proportion of carbon that is increased until SiC is formed close to the semi-conductive layer.

22. The method according to claim 13, wherein the thin antireflective layer is produced to comprise SiO2 in contact with the support, then SiOₓN_{y} with a proportion of nitrogen that is continuously reduced and a proportion of carbon that is continuously increased until SiC is formed close to the semi-conductive layer.
